(19) United States
(12) Patent Application Publication
(10) Pub. No.: US 2006/0055465 A1
(43) Pub. Date: Mar. 16, 2006

(54) Low voltage output current mirror method and apparatus thereof

(76) Inventors: Shui-Mu Lin, Tai Chung Hsien (TW); Chao-Hsuan Chuang, Chu Pei City (TW); Nien-Hui Kung, Miao Li Hsien (TW); Yiu-I Lin, Shu Lin City (TW); Der-Jiunn Wang, Hsin Chu City (TW); Jien-Sheng Chen, Miao Li Hsien (TW); Wei-Hsin Wei, Tai Chung Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/940,663

(22) Filed: Sep. 15, 2004

(51) Int. Cl. H03F 3/04

(52) U.S. Cl. 330/288

(57) ABSTRACT

A current mirror circuit that comprises a current mirror unit, a feedback unit and an amplifier unit is provided to output low voltage. The current mirror unit has a plurality of connecting ends, wherein one end couples to a current source, and the other end couples to a loading device. The feedback unit couples to the current mirror unit and the amplifier unit. The amplifier unit couples to the current mirror unit to lockup the voltages of the three notes configured in a plurality of MOS transistors of the current mirror unit. By way of the configuration of the present invention, the current mirror unit can detect an accurate current or map out accurately a push controlling current through the electrical characteristic of the amplifier unit and the feedback of the feedback unit.

### BACKGROUND OF THE INVENTION

1. Field of the Invention

The invention provides a method and its apparatus with low voltage output current mirror, especially a current mirror circuit which is able to output an accurate current and the apparatus which is useable in both the triode region and the saturation region.

2. Description of Related Art

A current mirror is a basic and important analog component that is widely applied to circuits for voltage bias and load for amplifier level. Applying the current mirror can insensitive a reaction due to variations in temperature and current. As such, a current mirror is an essential component in analog circuits. Because the current mirror is widely applied in various circuit designs for voltage bias and load drive, the accurately mapping character of the current mirror is very important. The performance of a current mirror depends on the stability and accuracy of its outputting current.

Referring to FIG. 1, a circuit scheme of the current mirror corresponding to the first related art is shown. There is a referred current Iref produced by a referred voltage through an output resistance R1. The Iref maps to a current mirror 10 to output current. However, because the bias range of the outputting current is too broad when the drain-source voltage of a metal-oxide-semiconductor transistor (MOS) is working in multi-hundred mini voltage, that is, the MOS transistor will approach the triode region, the current mirror 10 can not accurately output the desired current. That is, a related circuit design with a current mirror 10 performs less well than other circuits out a current. Besides, the efficiency of the ideal current mirror depends on the process.

Referring to FIG. 2, a circuit scheme of the current mirror corresponding to the second related art is shown. The circuit design of this current mirror 20 is a cascade structure. The disadvantage of this cascade current mirror is that the composed area is too large and the circuit needs a bias voltage Vb which determines the threshold voltage when the current decreases.

Referring to FIG. 3, a circuit scheme of the current mirror corresponding the third related art is shown. There is a referred voltage Vref produced by a referred current Iref through an output resistance R. This circuit design configuring the current mirror produces an m times current due to the ratio m to the resistor. The plurality of the MOS transistors work in the saturation region or the triode region. However, there are some disadvantages in this circuit design. Firstly, the resistor is hard to configure due to the inaccurate nature of the resistor, and, secondly, the layout of the resistors and the MOS requires a broad area.

### SUMMARY OF THE INVENTION

In order to deal with the deficiencies described above, the present invention provides a method and an apparatus for a low voltage outputting current mirror. The primary purpose of the present invention is to output an accurate current from a current mirror, and to provide a working circuit in both the triode region and the saturation region.

Because the circuit is able to work in both the triode region and the saturation region, the present invention provides a method for a current mirror to output a low voltage. The method derives a current source and configures a current mirror with a plurality of connecting ends. One of the connecting ends couples to the current source, and the connection of another end drives a loading device. There is an amplifier unit configured between the circuit of the current mirror and the loading device. The amplifier unit can adjust the voltages of the plurality of the connecting ends outputted from the circuit of the current mirror due to its electrical characteristic, thus equalizing the current working in both the current source and the loading device, and detect an accurate current or map an accurate push controlling current.

The present invention also provides an apparatus for a low voltage outputting current mirror. The apparatus comprises a current mirror whose one connecting end couples to a current source while the other end couples to a loading device. A feedback unit couples to the current mirror and an amplifier unit so as to feedback the voltage amplified by the amplifier unit to the current mirror to control multiple voltages in the current mirror to produce an accurate current, and an amplifier unit coupling to the current mirror so as to lockup the voltages of three notes of the multiple metal-oxide-semiconductor (MOS) transistors in the current mirror. Therefore, by way of the characteristic of the amplifier unit and the operation of the feedback unit, the current mirror can detect an accurate current or map an accurate push controlling current.

### BRIEF DESCRIPTION OF THE DRAWINGS

FIG. 1 is a circuitry diagram showing the current mirror according to the first embodiment of the related art.

FIG. 2 is a circuitry diagram showing the current mirror according to the second embodiment of the related art.

FIG. 3 is a circuitry diagram showing the current mirror according to the third embodiment of the related art.

FIG. 4 is a circuitry diagram showing the low voltage outputting current mirror with a N-type metal-oxide-semiconductor transistor according to the first embodiment of the present invention.

FIG. 5 is a circuitry diagram showing the low voltage outputting current mirror with a N-type metal-oxide-semiconductor transistor according to the second embodiment of the present invention.

FIG. 6 is a circuitry diagram showing the low voltage outputting current mirror with a P-type metal-oxide-semiconductor transistor according to the third embodiment of the present invention.

FIG. 7 is a circuitry diagram showing the low voltage outputting current mirror with a P-type metal-oxide-semiconductor transistor according to the fourth embodiment of the present invention.

FIG. 8 is a flowchart illustrating the method for low outputting voltage current mirror according to the present invention.

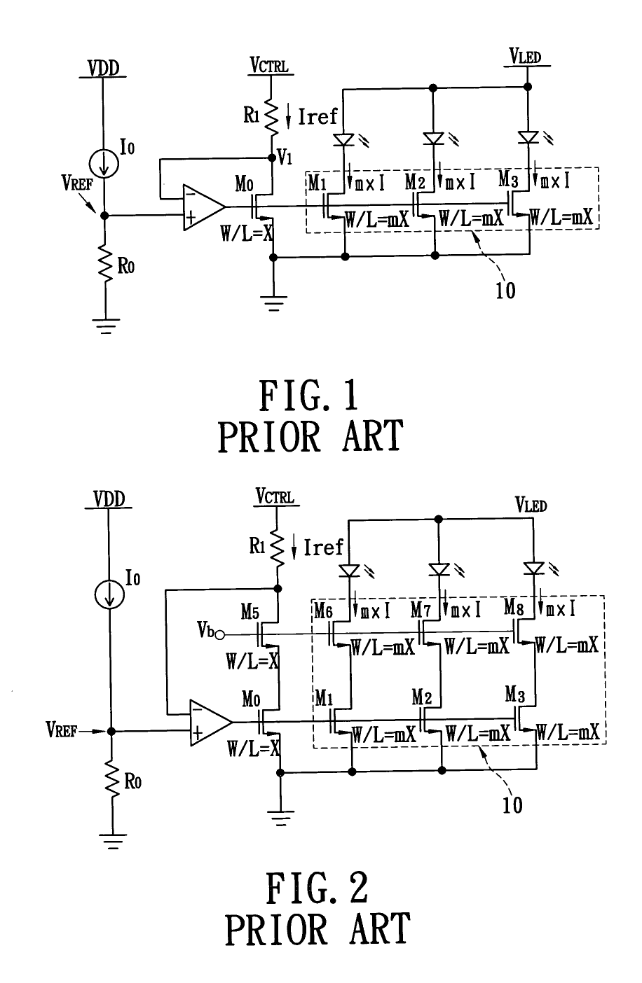

### DESCRIPTION OF THE PREFERRED EMBODIMENTS

In order to approach the purpose of the present invention, to clarify the skill, method and function in accordance with the present invention, the following detailed specification and drawings are disclosed below.

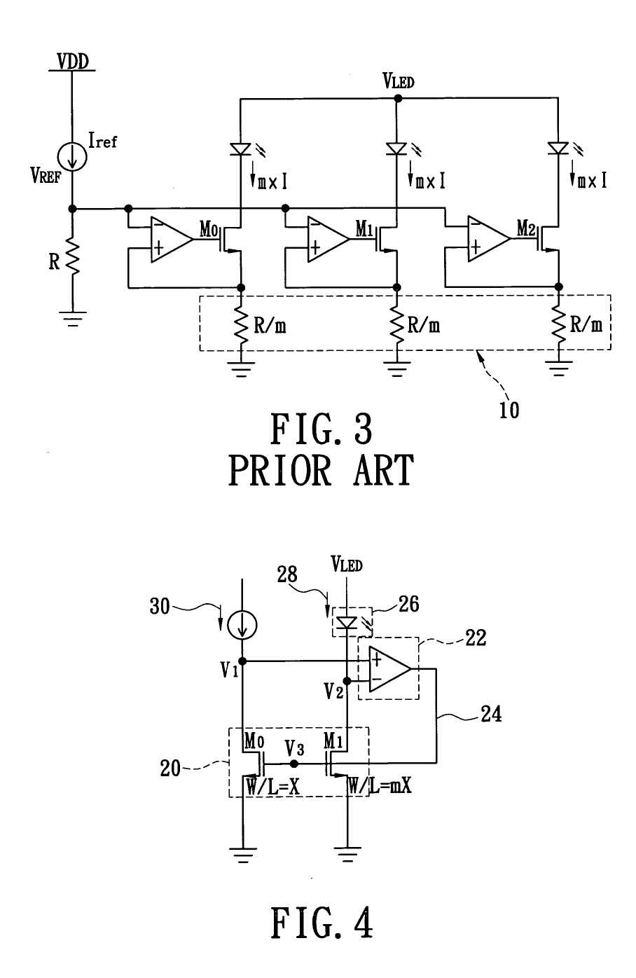

Referring to FIG. 4, a circuitry diagram shows the low voltage outputting current mirror with a N-type metal-oxide-semiconductor transistor according to the first embodiment of the present invention. A current source outputs a referred current 30, then a voltage V1 is generated from a drain of a metal-oxide-semiconductor (MOS) transistor M0 by the referred current 30, and the referred current 30 inputs a current mirror unit 20 comprised of two MOS transistor M0, M1. The voltage V1 inputs to an end of an amplifier unit 22. a voltage V2 generates from the drain of another MOS transistor M1 by a push controlling current 28 through a loading device 26, and inputs to the other end of the amplifier unit 22. The amplifier unit 22 is an operational amplifier (operational amplifier). Through the electrical characteristic of the operational amplifier, wherein the characteristic of an ideal operational amplifier is the input resistor is extremely large and the output resistor is equal to zero, that is able to make the amplifier unit 22 output so equal voltages that V1=V2.

The output ends of the operational amplifier couple to the gates of a plurality of the MOS transistors of the current mirror unit 20. A feedback unit 24 couples to the current mirror unit 20 to control the gate voltage V3 of the plurality of the MOS transistors. The voltages of the three notes described above are controlled by the electrical characteristic of the amplifier unit and co-operate with the feedback unit. A push controlling current 28 accurately maps through the referred current 30 by the current mirror unit 20.

As the means mentioned above, the first embodiment utilities the electrical characteristic of the operational amplifier to lockup the drain voltage of the current mirror, and use the feedback method to control the gate voltage of the current mirror. When the referred current Iref through the MOS transistor M0 is input to an end of the operational amplifier, the voltage of another end of the operational amplifieroperational amplifier will be offered by the loading device which is able to dedicated as a white-light diode. The operational amplifier will push the gate of the current mirror to lockup the drain voltage of the current mirror V1=V2. If the MOS transistor M0 is m times of the MOS transistor M1, the referred current Iref through the MOS transistor M0 maps m times into the MOS transistor M1 to push the white-light diode and control the current, so that a push controlling current can be mapped accurately (I=m×Iref).

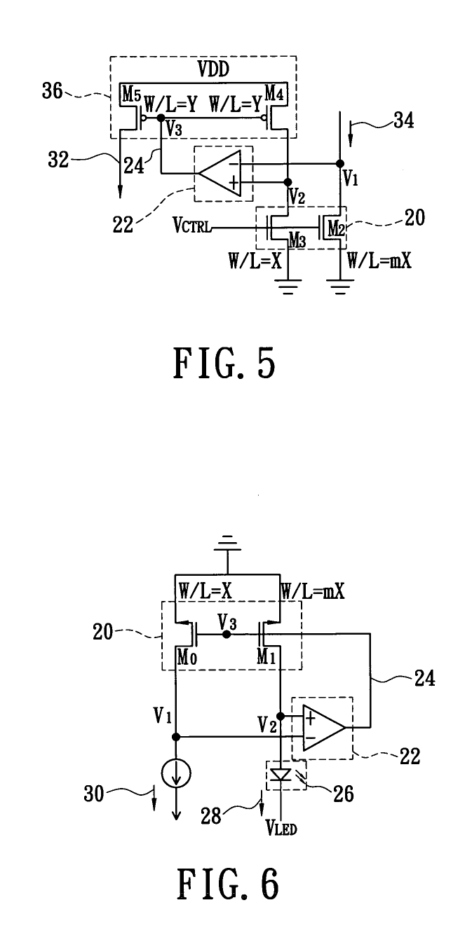

Referring to FIG. 5, a circuitry diagram shows the low voltage outputting current mirror with a N-type metal-oxide-semiconductor transistor according to the second embodiment of the present invention. There is a voltage V1 generated from the drain of the MOS transistor M2 by an estimating current 34 which also inputs into the current mirror 20 which is comprised of two MOS transistors M2, M3. The voltage V1 inputs to an end of an amplifier unit 22 which is an operational amplifier. By way of the connection of the output of the operational amplifier and the gate of the current mirror 36 comprised of two MOS transistors M4, M5, a feedback unit 24 is configured.

The source output of the MOS transistor M4 couples to another end of the operational amplifier and the drain of the MOS transistor M3 of the current mirror 20, so that the end of the operational amplifier generates a voltage V2. The gate voltage of the current mirror 20 is controlled by the external voltage Vctrl. Through the electrical characteristic of the operational amplifier (the input resistor is extremely large and the output resistor is equal to zero), the input voltages of the operational amplifier are similarly equal, V1=V2. The current mirror 36 works in the saturation region, so that the current through the MOS transistors M4, M5 is stable. Then an estimated current 32 can be mapped accurately by the current through the MOS transistor M4. The amount of the estimating current 34 can be detected by way of the characteristic of the current mirror.

As the means mentioned above, the second embodiment utilities the electrical characteristic of the operational amplifier to lockup the drain voltage of the current mirror and the gate voltage of another current mirror. The voltages of the three notes of the MOS transistor of the current mirror are lockup also. When the estimating current 34 through the MOS transistor M2 is inputting to and end of the operational amplifier, by way of the connection of the output of the operational amplifier and the gate of the current mirror 36 comprised by two MOS transistors M4, M5, a feedback unit 24 is configured.

The source output of the MOS transistor M4 couples to another end of the operational amplifier and the drain of the MOS transistor M3 of the current mirror 20, so that the end of the operational amplifier generates a voltage V2. By the means of the electrical characteristic of the operational amplifier the input voltages of the operational amplifier is similarly equal, V1=V2. If the MOS transistor M2 is m times of the MOS transistor M3 in the current mirror, the current through the MOS transistor M3 will be I/m. Therein the current mirror comprised of M2 and M2 works in the linear region or the saturation region, and the other current mirror comprised of M0 and M1 works in the saturation region, so that an estimated current can be mapped accurately. The amount of the estimating current 34 through the MOS transistor M2 can be detected by way of the characteristic of the current mirror.

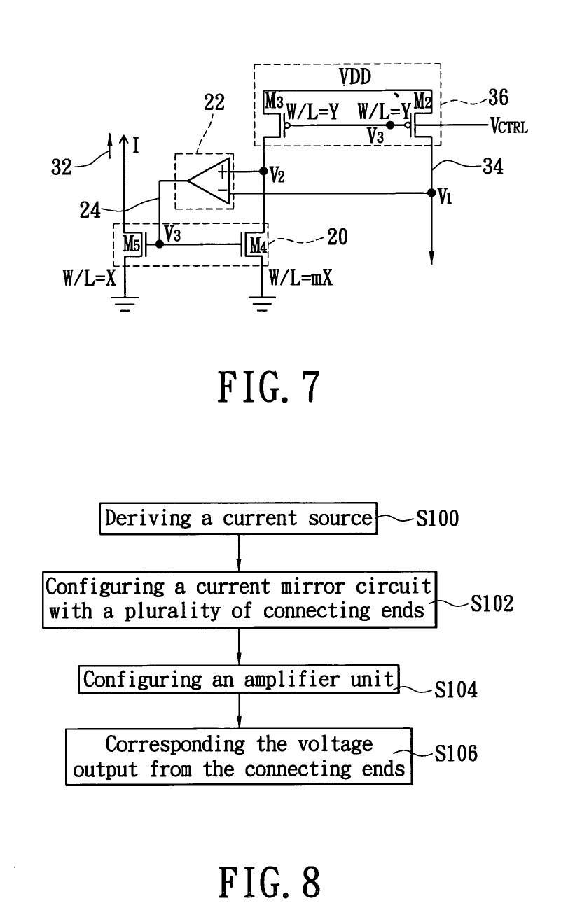

Referring to FIG. 6 and FIG. 7, FIG. 6 is a circuitry diagram showing the low voltage outputting current mirror with P-type MOS transistor according to the third embodiment of the present invention. The outcome of the operation is similar to the first embodiment according to the present invention as shown in FIG. 4. The difference between the third embodiment as shown in FIG. 6 and the first one as shown in FIG. 4 is the type of the MOS transistor is a N-type rather than a P-type. However, there is still a push controlling current being mapping accurately. FIG. 7 is a circuitry diagram showing the low voltage outputting current mirror with a P-type MOS transistor according to the fourth embodiment of the present invention. The outcome of the operation is similar to the second embodiment according to the present invention as shown in FIG. 5. The difference between the fourth embodiment as shown in FIG. 7 and the second one as shown in FIG. 5 is also that the type of the MOS transistor is a N-type rather than a P-type, however, there is still a push controlling current being mapping accurately. Since the operation of FIG. 6 and FIG. 7 are similar to FIG. 4 and FIG. 5, a detailed specification will not be described herein.

In these embodiments, the voltages described above V1, V2 and V3 will be lockup so that the voltages of the three notes will be equal and mapping a current more accurate. Therein the apparatus according to the present invention can be operated in both a triode region and a saturation region.

Referring to FIG. 8, a flowchart illustrating the method for a low outputting voltage current mirror according to the present invention is shown. The steps include deriving a current source S100, whose one end couples to a current mirror circuit configured to a plurality of connecting ends S102. One of the connecting ends couples to the current source, and the other end is configured to drive a loading device. There is an amplifier unit configured to S104 between the current mirror circuit and the loading device, to correspond to the voltages outputted from the connecting ends configured in the current mirror due to the electrical characteristic of the operational amplifier. By way of the correspondence of the voltages outputted from the connecting ends of the current mirror circuit, the current through the loading device will equal the current source during operation, so as to generate an accurate estimated current or mapping accurately a push controlling current. The push controlling current can be calculated by way of the formula Iout=m*Iref, wherein Iout is the amount of the push controlling current, m is the quantity of the multiple, and Iref is the amount of the referred current. The formula to calculate the amount of estimated current is Isense=Iout/m, wherein Isense is the amount of estimated current, m is the quantity of the multiple, and Iout is the amount of the push controlling current.

Although the invention has been described with reference to a particular embodiment thereof, it will be apparent to one of ordinary skill in the art that modifications to the described embodiment may be made without departing from the spirit of the invention. Accordingly, the scope of the invention will be defined by the attached claims not by the above detailed description.

What is claimed is:

1. A method of a low voltage output current mirror, comprising of the following steps:
deriving a current source;
configuring a current mirror circuit with a plurality of connecting ends, wherein one of said connecting ends couples to said current source, and the connection of another of said connecting ends is configured to drive a loading device;
configuring an amplifier unit between said current mirror circuit and said loading device; and
corresponding the voltages outputted from said connecting ends in said current mirror circuit by way of the electrical characteristic of said amplifier unit;
by way of the consistence of said voltages output from said connecting ends, the current of said current source and said loading device being correspondence to generate an accurate estimated current or mapping accurately a push controlling current.

2. The method of a low voltage output current mirror according to claim 1, wherein said loading device is a white-light diode.

3. The method of a low voltage output current mirror according to claim 1, wherein said current mirror unit comprises a plurality of metal-oxide-semiconductor (MOS) transistors.

4. The method of a low voltage output current mirror according to claim 1, wherein said amplifier unit is an operational amplifier.

5. The method of a low voltage output current mirror according to claim 3, wherein said MOS transistors are N-type channeled.

6. The method of a low voltage output current mirror according to claim 3, wherein said MOS transistors are P-type channeled.

7. An apparatus of a low voltage output current mirror, comprising:
a current mirror unit whose one end couples to a current source and another end couples to a loading device;
a feedback unit coupling to said current mirror unit and an amplifier unit, feedback, the voltage amplified by said amplifier unit being fedback to said current mirror unit to control the voltages generated from said current mirror unit so as to generate an accurate current; and
an amplifier unit coupling to said current mirror unit to lockup the voltages of the three notes configured in a plurality of the metal-oxide-semiconductor (MOS) transistors of said current mirror unit.

8. The apparatus of a low voltage output current mirror according to claim 7, wherein said loading device is a white-light diode.

9. The apparatus of a low voltage output current mirror according to claim 7, wherein said current mirror unit comprises a plurality of metal-oxide-semiconductor (MOS) transistors.

10. The method of a low voltage output current mirror according to claim 7, wherein said amplifier unit is an operational amplifier.

11. The method of a low voltage output current mirror according to claim 9, wherein said MOS transistors are N-type channeled.

12. The method of a low voltage output current mirror according to claim 9, wherein said MOS transistors are P-type channeled.
